(19) United States
(12) Patent Application Publication
(10) Pub. No.: US 2025/0139814 A1
(43) Pub. Date: May 1, 2025

(54) OVERLAY MARK DESIGN ENABLING LARGE OVERLAY MEASUREMENT

(71) Applicant: KLA Corporation, Milpitas, CA (US)

(72) Inventor: Mark Ghinovker, Yoqneam Ilit (IL)

(21) Appl. No.: 18/421,580

(22) Filed: Jan. 24, 2024

Related U.S. Application Data
(60) Provisional application No. 63/594,956, filed on Nov. 1, 2023.

(51) Int. Cl. G06T 7/73; G03F 1/36; G03F 7/00; G06T 7/00

(52) U.S. Cl. CPC G06T 7/73; G03F 1/36; G03F 7/70633; G03F 7/706837; G06T 7/0004

(57) ABSTRACT

An overlay metrology system may receive images of an overlay target on a sample, where the overlay target includes Moiré structures in which first-layer features and second-layer features partially overlap, where overlap regions include regions of overlap between the first-layer and second-layer features, where non-overlap regions include regions of non-overlap between the first-layer and second-layer features. The system may further, determine a coarse overlay measurement based at least in part on the one or more non-overlap regions of the one or more images, determine a fine overlay measurement based at least in part on the one or more overlap regions of the one or more images, and generate an output overlay measurement based on the coarse overlay measurement and the fine overlay measurement.

### CROSS-REFERENCE TO RELATED APPLICATION

The present application claims the benefit under 35 U.S.C. § 119(e) of U.S. Provisional Application Ser. No. 63/594,956, filed Nov. 1, 2023, naming Mark Ghinovker as inventor, which is incorporated herein by reference in the entirety.

### TECHNICAL FIELD

The present disclosure relates generally to overlay metrology and, more particularly, to overlay metrology in applications with large physical overlay errors.

### BACKGROUND

Overlay metrology provides measurements of a relative alignment of features fabricated with different lithographic exposures. Some overlay measurement techniques utilize dedicated overlay targets having periodic features (e.g., diffraction gratings, or the like). However, periodic overlay targets may have a limited measurable range of overlay values that may be unambiguously measured, where the range of overlay values may be generally related to the pitch of the periodic features. There is therefore a need to develop systems and methods to address the above deficiencies.

### SUMMARY

In embodiments, the techniques described herein relate to an overlay metrology system including a controller including one or more processors configured to execute program instructions stored in a memory device, where the program instructions are configured to cause the one or more processors to implement a metrology recipe by receiving one or more images of an overlay target on a sample, where the overlay target includes one or more Moiré structures, where a respective one of the one or more Moiré structures is formed from first-layer features with a first pitch on a first layer of the sample and further with second-layer features with a second pitch on a second layer of the sample, where the first-layer features and the second-layer features in the respective one of the one or more Moiré structures partially overlap, where one or more overlap regions include regions of overlap between the first-layer features and the second-layer features, where one or more non-overlap regions include regions of non-overlap with one of the first-layer features or the second-layer features and further include one or more non-overlapping features; determining a coarse overlay measurement between the first layer and the second layer based at least in part on the one or more non-overlap regions of the one or more images; determining a fine overlay measurement between the first layer and the second layer based at least in part on the one or more overlap regions of the one or more images; and generating an output overlay measurement based on the coarse overlay measurement and the fine overlay measurement.

In embodiments, the techniques described herein relate to an overlay metrology system, where the program instructions are further configured to cause the one or more processors to implement the metrology recipe by controlling one or more process tools via one or more control signals based on the output overlay measurement.

In embodiments, the techniques described herein relate to an overlay metrology system, where the one or more non-overlapping features include an overlap boundary between one of the one or more overlap regions and one of the one or more non-overlap regions.

In embodiments, the techniques described herein relate to an overlay metrology system, where the one or more non-overlapping features include a non-overlap boundary between one of the one or more non-overlap regions and an outer boundary of the overlay target.

In embodiments, the techniques described herein relate to an overlay metrology system, where the one or more non-overlapping features include an outer boundary of the overlay target.

In embodiments, the techniques described herein relate to an overlay metrology system, where generating the output overlay measurement based on the coarse overlay measurement and the fine overlay measurement includes unwrapping the fine overlay measurement using the coarse overlay measurement.

In embodiments, the techniques described herein relate to an overlay metrology system, where the fine overlay measurement has a measurement range, where generating the output overlay measurement based on the coarse overlay measurement and the fine overlay measurement includes adjusting the fine overlay measurement by an integer number of the measurement range based on the coarse overlay measurement.

In embodiments, the techniques described herein relate to an overlay metrology system, where the overlay target provides the output overlay measurement along one or more measurement directions, where the overlay target includes a first set of Moiré structures, where the first-layer features in the first set of Moiré structures have a pitch P and the second-layer features in the first set of Moiré structures have a pitch Q; and a second set of Moiré structures, where the first-layer features in the second set of Moiré structures have the pitch Q and the second-layer features in the second set of Moiré structures have the pitch P.

In embodiments, the techniques described herein relate to an overlay metrology system, where the one or more Moiré structures includes two or more Moiré structures, where at least one of the two or more Moiré structures has periodicity along a first measurement direction, where at least one of the two or more Moiré structures has periodicity along a second measurement direction different than the first measurement direction, where the output overlay measurement includes a first output overlay measurement associated with the first measurement direction and a second output overlay measurement associated with the second measurement direction.

In embodiments, the techniques described herein relate to an overlay metrology system including an imaging sub-system including one or more detectors to image a sample in response to illumination from an illumination source; and a controller communicatively coupled to the imaging sub-system, the controller including one or more processors configured to execute program instructions stored in a memory device, where the program instructions are configured to cause the one or more processors to implement a metrology recipe by receiving one or more images of an overlay target on the sample from the imaging sub-system, where the overlay target includes one or more Moiré structures, where a respective one of the one or more Moiré structures is formed from first-layer features with a first pitch on a first layer of the sample and further from second-layer features with a second pitch on a second layer of the sample, where the first-layer features and the second-layer features in the respective one of the one or more Moiré structures partially overlap, where one or more overlap regions include regions of overlap between the first-layer features and the second-layer features, where one or more non-overlap regions include regions of non-overlap with one of the first-layer features or the second-layer features and further include one or more non-overlapping features; determining a coarse overlay measurement between the first layer and the second layer based at least in part on the one or more non-overlap regions of the one or more images; determining a fine overlay measurement between the first layer and the second layer based at least in part on the one or more overlap regions of the one or more images; and generating an output overlay measurement based on the coarse overlay measurement and the fine overlay measurement.

In embodiments, the techniques described herein relate to an overlay metrology system, where the imaging sub-system is an optical imaging sub-system, where the illumination includes light.

In embodiments, the techniques described herein relate to an overlay metrology system, where the imaging sub-system is a particle-beam imaging sub-system, where the illumination includes at least one of an electron beam, an ion beam, or a neutral-particle beam.

In embodiments, the techniques described herein relate to an overlay metrology system, where the program instructions are further configured to cause the one or more processors to implement the metrology recipe by controlling one or more process tools via one or more control signals based on the output overlay measurement.

In embodiments, the techniques described herein relate to an overlay metrology system, where the one or more non-overlapping features include an overlap boundary between one of the one or more overlap regions and one of the one or more non-overlap regions.

In embodiments, the techniques described herein relate to an overlay metrology system, where the one or more non-overlapping features include a non-overlap boundary between one of the one or more non-overlap regions and an outer boundary of the overlay target.

In embodiments, the techniques described herein relate to an overlay metrology system, where the one or more non-overlapping features include an outer boundary of the overlay target.

In embodiments, the techniques described herein relate to an overlay metrology system, where generating the output overlay measurement based on the coarse overlay measurement and the fine overlay measurement includes unwrapping the fine overlay measurement using the coarse overlay measurement.

In embodiments, the techniques described herein relate to an overlay metrology system, where the fine overlay measurement has a measurement range, where generating the output overlay measurement based on the coarse overlay measurement and the fine overlay measurement includes adjusting the fine overlay measurement by an integer number of the measurement range based on the coarse overlay measurement.

In embodiments, the techniques described herein relate to an overlay metrology system, where the overlay target provides the output overlay measurement along one or more measurement directions, where the overlay target includes a first set of Moiré structures, where the first-layer features in the first set of Moiré structures have a pitch P and the second-layer features in the first set of Moiré structures have a pitch Q; and a second set of Moiré structures, where the first-layer features in the second set of Moiré structures have the pitch Q and the second-layer features in the second set of Moiré structures have the pitch P.

In embodiments, the techniques described herein relate to an overlay metrology system, where the one or more Moiré structures includes two or more Moiré structures, where at least one of the two or more Moiré structures has periodicity along a first measurement direction, where at least one of the two or more Moiré structures has periodicity along a second measurement direction different than the first measurement direction, where the output overlay measurement includes a first output overlay measurement associated with the first measurement direction and a second output overlay measurement associated with the second measurement direction.

In embodiments, the techniques described herein relate to an overlay method including generating one or more images of an overlay target on a sample, where the overlay target includes one or more Moiré structures, where a respective one of the one or more Moiré structures is formed from first-layer features with a first pitch on a first layer of the sample and further from second-layer features with a second pitch on a second layer of the sample, where the first-layer features and the second-layer features in the respective one of the one or more Moiré structures partially overlap, where one or more overlap regions include regions of overlap between the first-layer features and the second-layer features, where one or more non-overlap regions include regions of non-overlap with one of the first-layer features or the second-layer features and further include one or more non-overlapping features; determining a coarse overlay measurement between the first layer and the second layer based at least in part on the one or more non-overlap regions of the one or more images; determining a fine overlay measurement between the first layer and the second layer based at least in part on the one or more overlap regions of the one or more images; and generating an output overlay measurement based on the coarse overlay measurement and the fine overlay measurement.

In embodiments, the techniques described herein relate to an overlay target including one or more Moiré structures, where a respective one of the one or more Moiré structures is formed from first-layer features with a first pitch on a first layer of a sample and further from second-layer features with a second pitch on a second layer of the sample, where the first-layer features and the second-layer features in the respective one of the one or more Moiré structures partially overlap, where one or more overlap regions include regions of overlap between the first-layer features and the second-layer features, where one or more non-overlap regions include regions of non-overlap with one of the first-layer features or the second-layer features and further include one or more non-overlapping features, where an output overlay measurement between the first layer and the second layer is determinable based on a coarse overlay measurement and a fine overlay measurement, where the coarse overlay measurement is based at least in part on the one or more non-overlap regions in one or more images, where the fine overlay measurement is based at least in part on the one or more overlap regions of the one or more images.

In embodiments, the techniques described herein relate to an overlay target, where the one or more non-overlapping features include an overlap boundary between one of the one or more overlap regions and one of the one or more non-overlap regions.

In embodiments, the techniques described herein relate to an overlay target, where the one or more non-overlapping features include a non-overlap boundary between one of the one or more non-overlap regions and an outer boundary of the overlay target.

In embodiments, the techniques described herein relate to an overlay target, where the one or more non-overlapping features include an outer boundary of the overlay target.

In embodiments, the techniques described herein relate to an overlay target, where the overlay target provides the output overlay measurement along one or more measurement directions, where the overlay target includes a first set of Moiré structures, where the first-layer features in the first set of Moiré structures have a pitch P and the second-layer features in the first set of Moiré structures have a pitch Q; and a second set of Moiré structures, where the first-layer features in the second set of Moiré structures have the pitch Q and the second-layer features in the second set of Moiré structures have the pitch P.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a block diagram depicting an overlay metrology system, in accordance with one or more embodiments of the present disclosure.

FIG. 1B is a simplified schematic of the overlay metrology system configured as an optical system, in accordance with one or more embodiments of the present disclosure.

FIG. 1C is a simplified schematic of the overlay metrology system configured as a particle beam system, in accordance with one or more embodiments of the present disclosure.

FIG. 2A is a simplified top view of a Moiré structure, in accordance with one or more embodiments of the present disclosure.

FIG. 2B is a simplified cross-sectional view of a Moiré structure, in accordance with one or more embodiments of the present disclosure.

FIG. 2C is a top view of an overlay target including multiple Moiré structures, in accordance with one or more embodiments of the present disclosure.

FIG. 3 is a diagram depicting ambiguous measurement conditions associated with large physical overlay error, in accordance with one or more embodiments of the present disclosure.

FIG. 4 is a top view of the overlay target 104 in FIG. 2C shown with a physical overlay error, in accordance with one or more embodiments of the present disclosure.

FIG. 5 is a flow diagram illustrating steps performed in a method 500 for overlay metrology, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing accurate overlay measurements with an overlay target having one or more Moiré regions that include overlapping periodic features with different pitches to form a Moiré structure and further include one or more single-layer regions with features on a single layer. The Moiré regions may form or be associated with a robust advanced imaging metrology (r-AIM) target. Such a configuration may be suitable for providing accurate overlay measurements over a large range of physical overlay values.

It is contemplated herein that typical techniques for generating overlay measurements based on an overlay target with periodic structures may have a limited range of measurable physical overlay errors. When a physical overlay error is outside of this window (e.g., when a physical overlay error is sufficiently large), a resulting measurement may be ambiguous. For example, a maximum physical overlay measurable by a traditional advanced imaging metrology (AIM) target may be approximately ±p/4, where p is a pitch of features of the target. As another example, a maximum physical overlay measurable by an r-AIM target may be approximately ±pₘ/(4Gₘ), where pₘ is a Moiré pitch associated with double diffraction by periodic features with different pitches and Gm is a Moiré gain factor associated with a difference between the different pitches.

In embodiments, a fine overlay measurement is generated based one or more images of the one or more Moiré regions, while a coarse overlay measurement is generated based on one or more images of the one or more single-layer regions. The fine overlay measurement may be generated using any suitable technique. Overlay metrology based on Moiré effects are generally described in U.S. Pat. No. 11,164,307 issued on Nov. 2, 2021; U.S. Pat. No. 11,256,177 issued on Feb. 22, 2022; U.S. Pat. No. 10,705,435 issued on Jul. 7, 2020; U.S. Pat. No. 11,841,621 issued on Dec. 12, 2023; and U.S. Pat. No. 11,355,375 issued on Jun. 7, 2022; all of which are incorporated herein by reference in its entirety.

The coarse overlay measurement may then be used to resolve any ambiguity in the fine overlay measurement such as, but not limited to, ambiguity associated with a physical overlay error.

Some embodiments of the present disclosure are directed to an overlay target having one or more Moiré regions and one or more single-layer regions. Some embodiments of the present disclosure are directed to an overlay metrology system designed to generate an overlay measurement based on one or more images of an overlay target having one or more Moiré regions and one or more single-layer regions, where the overlay measurement is based on a fine overlay measurement associated with Moiré regions and a coarse overlay measurement based on single-layer regions. Some embodiments of the present disclosure are directed to an overlay metrology method based on one or more images of an overlay target having one or more Moiré regions and one or more single-layer regions, where the overlay measurement is based on a fine overlay measurement associated with Moiré regions and a coarse overlay measurement based on single-layer regions.

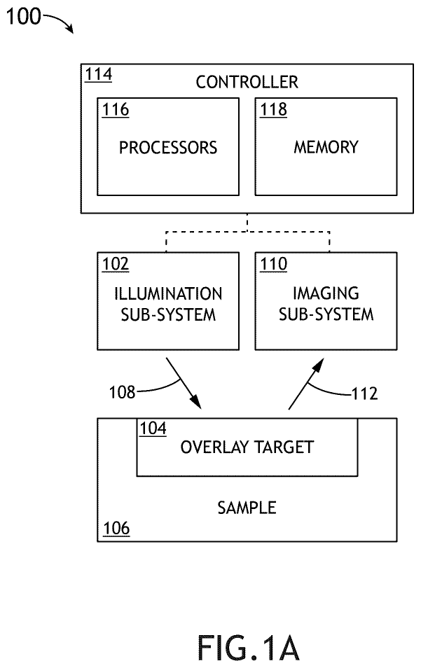

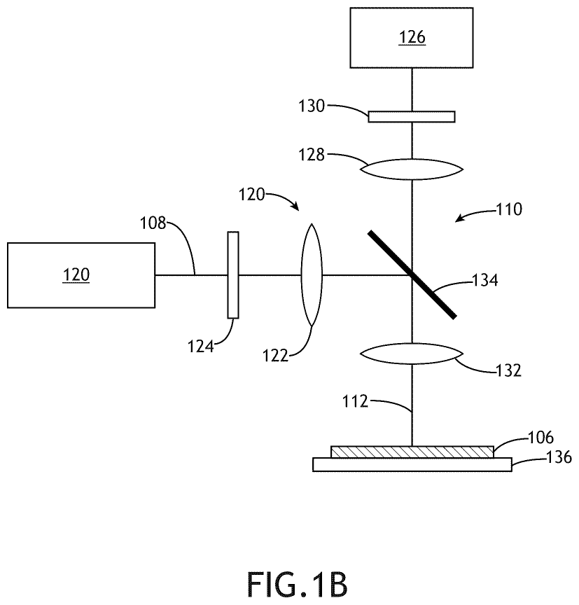

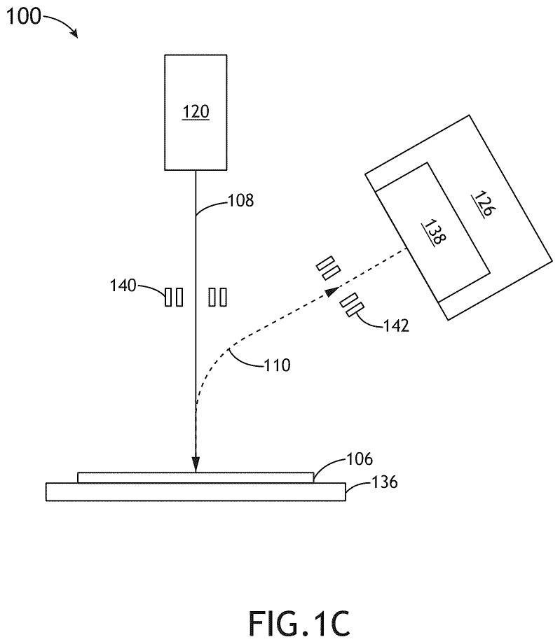

Referring now to FIGS. 1A-5, systems and methods for overlay metrology are described in greater detail, in accordance with one or more embodiments of the present disclosure.

FIG. 1A is a block diagram depicting an overlay metrology system 100, in accordance with one or more embodiments of the present disclosure. In embodiments, an overlay metrology system 100 includes an illumination sub-system 102 configured to illuminate an overlay target 104 on a sample 106 with illumination 108 and an imaging sub-system 110 configured to generate one or more images of the sample 106. For example, the imaging sub-system 110 may collect a signal from the sample 106 (referred to herein as a sample signal 112) and image the overlay target 104 with at least a portion of the sample signal 112.

The overlay metrology system 100 may utilize any type of illumination 108 as the basis for imaging an overlay target 104. In embodiments, the overlay metrology system 100 is an optical system. In this configuration, the illumination 108 includes one or more illumination beams formed as light (e.g., photons). In embodiments, the overlay metrology system 100 is a particle-beam system. In this configuration, the illumination 108 includes one or more illumination beams formed as particle beams such as, but not limited to, one or more electron beams, one or more ion beams, or one or more neutral-particle beams.

FIG. 1B is a simplified schematic of the overlay metrology system 100 configured as an optical system, in accordance with one or more embodiments of the present disclosure. FIG. 1C is a simplified schematic of the overlay metrology system 100 configured as a particle beam system, in accordance with one or more embodiments of the present disclosure.

In embodiments, the overlay metrology system 100 includes a controller 114 including one or more processors 116 configured to execute program instructions maintained on memory 118, or memory medium. In this regard, the one or more processors 116 of controller 114 may execute any of the various process steps described throughout the present disclosure. Further, the controller 114 may be communicatively coupled to any component of the overlay metrology system 100 including, but not limited to, the illumination sub-system 102, the imaging sub-system 110, or any component therein.

In embodiments, the overlay metrology system 100 is configurable to generate one or more overlay measurements associated with an overlay target 104 including a one or more Moiré regions and one or more single-layer regions. For example, the overlay metrology system 100 may be configurable to generate one or more fine overlay measurements based on the Moiré regions and one or more coarse overlay measurements based on single-layer regions. In this way, an output overlay measurement may be generated by using the coarse overlay measurement to resolve ambiguities in the fine overlay measurement such as, but not limited to, ambiguities associated with the use of periodic signals when generating the fine overlay measurement.

The overlay metrology system 100 may be configurable to generate measurements based on any number of metrology recipes defining various aspects of the overlay target 104 (e.g., a target design) or measurement parameters of the imaging sub-system 110 suitable for generating an overlay measurement of a particular overlay target 104 with a particular target design. Put another way, the overlay metrology system 100 may be configured to provide a selected type of measurement for a selected overlay target design. For example, a metrology recipe may include various parameters associated with a design of the overlay target 104 such as, but not limited to, positions and orientations of sample features (e.g., pitches of grating features along particular directions). By way of another example, a metrology recipe may include various parameters associated with the position of the sample 106 during a measurement such as, but not limited to, a height, an orientation, whether the sample 106 is static during a measurement, or whether the sample 106 is in motion during a measurement (along with associated parameters describing the speed, scan pattern, or the like). By way of another example, a metrology recipe may include parameters of the illumination 108 such as, but not limited to, an illumination wavelength, an illumination pupil distribution (e.g., a distribution of illumination angles and associated intensities of illumination at those angles), a polarization of incident illumination, or a spatial distribution of illumination. By way of another example, a metrology recipe may include collection parameters associated with collection or filtering of the sample signal 112 such as, but not limited to, a collection pupil distribution, collection field stop settings to select portions of the overlay target 104 of interest for imaging, a polarization of sample signal 112, wavelength filters, or parameters for controlling one or more detectors.

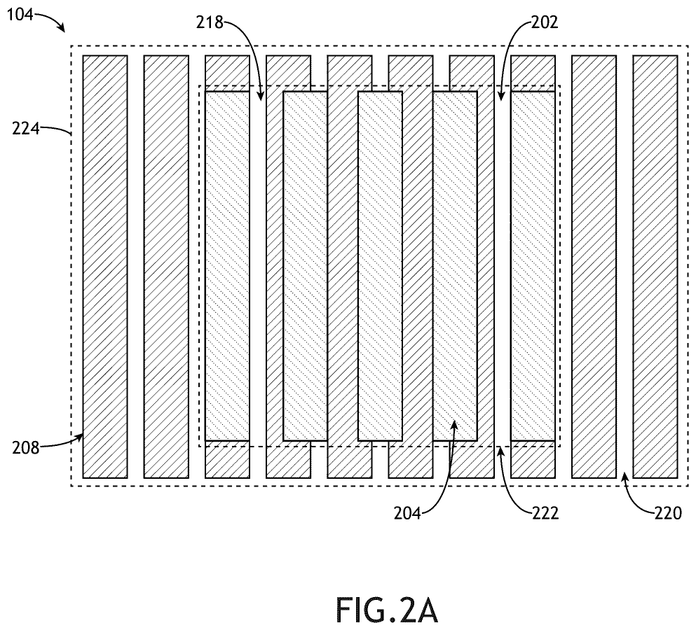

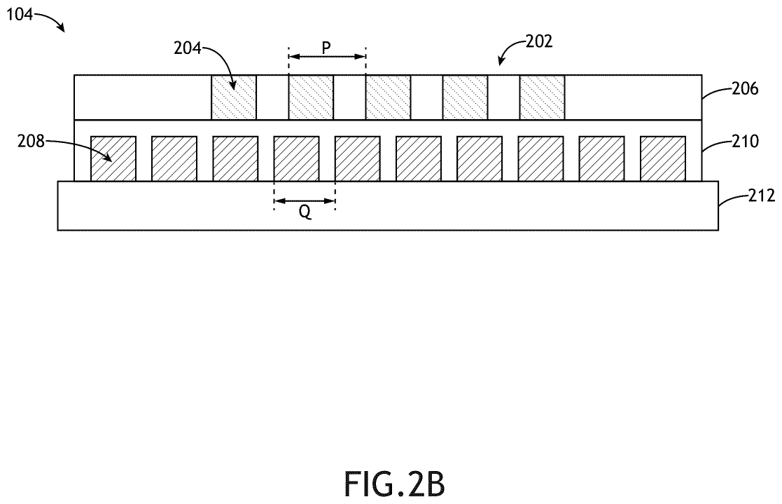

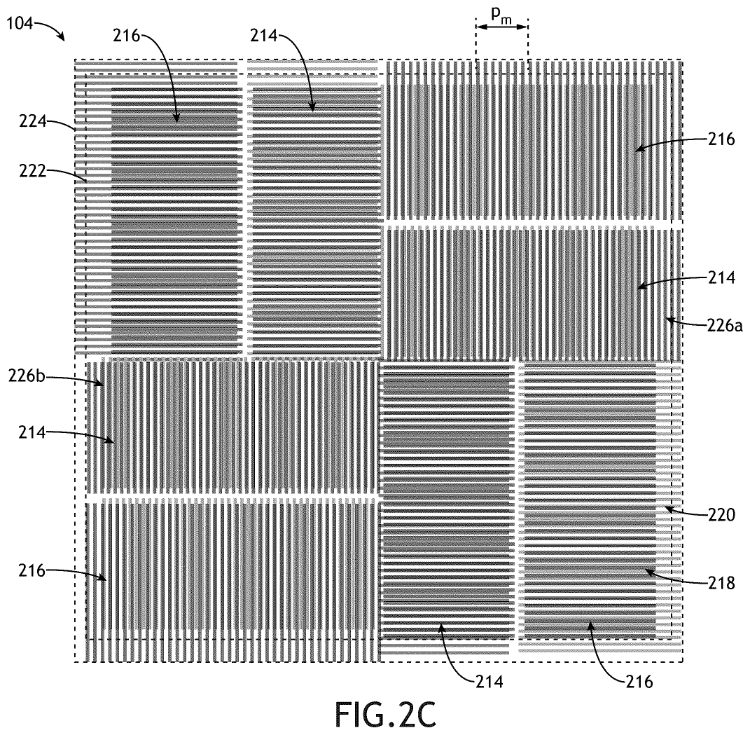

Referring now to FIGS. 2A-5, systems and methods for unambiguous overlay measurements on an overlay target 104 are described in greater detail, in accordance with one or more embodiments of the present disclosure.

FIG. 2A is a simplified top view of a Moiré structure 202, in accordance with one or more embodiments of the present disclosure. FIG. 2B is a simplified cross-sectional view of a Moiré structure 202, in accordance with one or more embodiments of the present disclosure.

In embodiments, a Moiré structure 202 includes first-layer features 204 on a first layer 206 of the sample 106 and second-layer features 208 on a second layer 210 of the sample 106, where the first-layer features 204 and the second-layer features 208 at least partially overlap. Further, the first-layer features 204 and the second-layer features 208 may be periodic with different pitches. For example, FIG. 2A depicts a configuration in which the first-layer features 204 have a pitch P and the second-layer features 208 have a pitch Q. As a result, the first-layer features 204 and the second-layer features 208 in regions of overlap may be together referred to as a grating-over-grating structure and may produce Moiré effects based on the different pitches.

The first layer 206 and the second layer 210 may be at any location within the sample 106. For example, as illustrated in FIG. 2B, the first-layer features 204 and the second-layer features 208 may be formed on a substrate 212. However, this is merely an illustration and should not be interpreted as limiting on the scope of the present disclosure. The sample 106 may include any number of additional layers between the first layer 206 and the second layer 210, and/or on either side of the first layer 206 or the second layer 210.

In embodiments, an overlay target 104 includes one or more Moiré structures 202, where the different Moiré structures 202 may have different configurations. For example, an overlay target 104 may include one or more pairs of Moiré structures 202 with inverted pitch configurations. As an illustration, an overlay target 104 may include a first Moiré structure 202 as depicted in FIGS. 2A and 2B in which the first-layer features 204 have pitch P and the second-layer features 208 have pitch Q (e.g., a P/Q or a P over Q Moiré structure 202), and may further include a second Moiré structure 202 in which the first-layer features 204 have pitch Q and the second-layer features 208 have pitch P (e.g., a Q/P or a Q over P Moiré structure 202). Such a pair of inverted Moiré structures 202 may provide various benefits including, but not limited to, self-configuration and/or self-calibration. Overlay metrology using pairs of inverted Moiré structures 202 are generally described in U.S. Pat. No. 10,705,435 issued on Jul. 7, 2020; and U.S. Pat. No. 11,841,621 issued on Dec. 12, 2023; both of which are incorporated herein by reference in their entireties. As another example, an overlay target 104 may include multiple Moiré structure 202 with the same configuration (e.g., as different cells). Such a configuration may be suitable for increasing an accuracy or robustness of a measurement.

FIG. 2C is a top view of an overlay target 104 including multiple Moiré structures 202, in accordance with one or more embodiments of the present disclosure. In particular, the overlay target 104 in FIG. 2C includes a first set 214 of cells with Moiré structures 202 having a P/Q configuration and a second set 216 of cells of Moiré structures 202 having a Q/P configuration. Further, a Moiré pitch (pₘ) is visible.

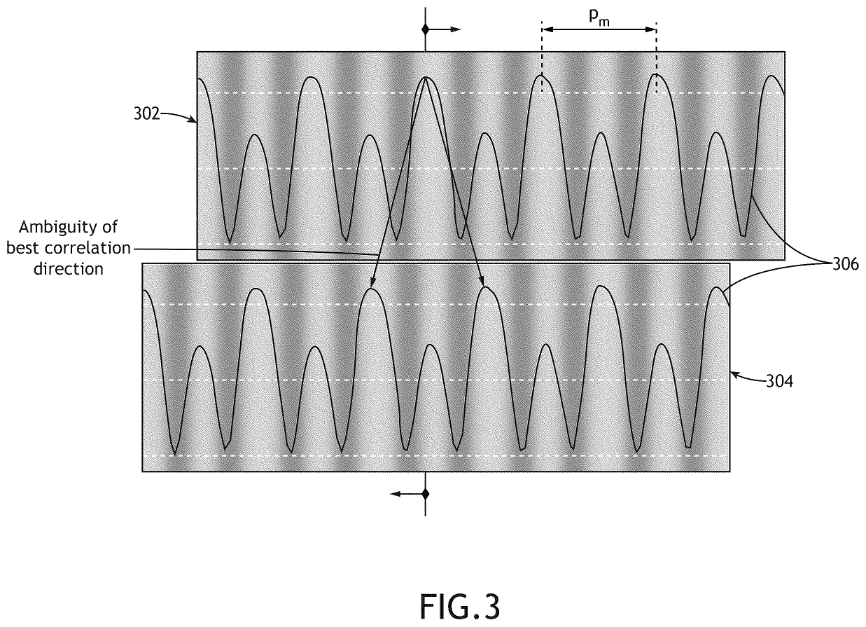

FIG. 3 is a diagram depicting ambiguous measurement conditions associated with large physical overlay error, in accordance with one or more embodiments of the present disclosure.

It is contemplated herein that overlay may be determined based on one or more images of an overlay target 104 using a variety of techniques. For example, one non-limiting technique for determining overlay is to separately find centers of symmetry of sets of cells with similar structures (e.g., the first set 214 of cells and the second set 216 of cells in FIG. 2C), and then to determine an overlay measurement based on differences between these centers of symmetry. As an illustration, a center of symmetry of the first set 214 of cells in FIG. 2C may be, but is not required to be, generated by identifying regions of interest (ROIs) associated with the cell 226a and the cell 226b and rotating a portion of the image associated with the cell 226b by 180 degrees (which corresponds to flipping the portion of the image when features are symmetric). Then, a position associated with a point of rotation providing a highest correlation between the ROIs corresponds to a center of symmetry of the set 214 of cells. Such a process may then be repeated for the second set 216 of cells to provide an overlay determination.

However, FIG. 3 depicts conditions in which the correlation used to generate a center of symmetry measurement may be ambiguous such that the resulting overlay measurement may also be ambiguous. In particular, FIG. 3 shows a first image 302 of a Moiré structure 202 corresponding to a region of interest of a cell in a top right quadrant of an overlay target 104 as depicted in FIG. 2C (e.g., a region of interest in cell 226a in FIG. 2C), along with a second image 304 corresponding to a region of interest of a cell in a bottom left quadrant of the same overlay target 104 (e.g., a region of interest in cell 226b in FIG. 2C). Further, the solid lines 306 correspond to a signal strength overlaid on the respective images. In both the first image 302 and the second image 304, fringes associated with a Moiré pitch (pₘ) are visible.

In FIG. 3, a physical overlay error induces a shift of the visible Moiré fringes in the first image 302 of pₘ/4 to the right and a shift of the visible Moiré fringes in the flipped second image 304 of pₘ/4 to the left. However, the large shifts lead to an ambiguity in this correlation process and thus an ambiguity in the center of symmetry determination.

In a general sense, the repetitive nature of a periodic signal such as the Moiré fringes in these images may necessitate additional information in order to determine the direction and/or extent of a fringe shift. When the fringe shift is known to be small (e.g., due to tightly-controlled fabrication tolerances), this information may provide certainty as to the direction of fringe shifts and thus certainty in a center of symmetry measurement. However, when the fringe shift may potentially be larger, additional information beyond the first image 302 and the second image 304 is needed to determine the extent and/or direction of fringe shifts. As one example, if the fringe shifts exceed a period of the fringes, additional information may be necessary to determine a number of periods the fringes are shifted. As another example, even when the fringe shifts are smaller than a period of the fringes, there may still be ambiguity regarding the direction and/or magnitude of the shift.

In embodiments, an overlay target 104 includes one or more Moiré structures 202 arranged such that the first-layer features 204 and the second-layer features 208 have different spatial extents (e.g., different boundaries). As a result, overlapping grating-over-grating structures (e.g., areas of overlap between the first-layer features 204 and the second-layer features 208) may lie within one or more overlap regions 218, whereas areas with non-overlapping features may lie within one or more non-overlap regions 220.

For example, FIG. 2A depicts a configuration with a single Moiré structure 202 in which second-layer features 208 have a larger spatial extent than the first-layer features 204. Further, the overlay target 104 includes an overlap region 218 and a non-overlap region 220 fully surrounding the overlap region 218. In FIG. 2A, the overlap region 218 is bounded by an overlap boundary 222, while the non-overlap region 220 is located between the overlap boundary 222 and a non-overlap boundary 224.

As another example, FIG. 2C depicts a configuration with multiple Moiré structures 202 in which second-layer features 208 across the whole overlay target 104 have a larger spatial extent than the first-layer features 204 across the whole overlay target 104. In this configuration, an overlap region 218 includes overlapping portions of the various Moiré structures 202 across the overlay target 104. In this way, the non-overlap boundary 224 may correspond to the overlay target 104 as a whole, whereas the overlap boundary 222 may correspond to an inner region of the overlay target 104 that includes overlapping grating-over-grating structures.

However, it is to be understood that FIGS. 2A and 2C along the above descriptions are provided solely for illustrative purposes and should not be interpreted as limiting the scope of the present disclosure. For example, an overlay target 104 may include any number of Moiré structures 202 having features with different spatial extents. As another example, an overlay target 104 may include any number or arrangement of overlap regions 218 and non-overlap regions 220.

It is contemplated herein that the non-overlap regions 220 may be used to provide a coarse overlay measurement that may resolve ambiguities associated with a fine overlay measurement from one or more overlap regions 218. For example, an ambiguity in a fine overlay measurement associated with periodic signals in one or more overlap regions 218 may be resolved by selecting a value closest to a coarse overlay measurement associated with one or more non-overlap regions 220.

A coarse overlay measurement may be generated using any suitable technique based at least in part on one or more non-overlap regions 220 (or portions thereof).

In embodiments, a coarse overlay measurement is generated based on observable boundaries between one or more overlap regions 218 and one or more non-overlap regions 220. For example, different features and/or signal levels may be present these different regions such that the boundaries between them may be measurable. Further, in some applications, an outer boundary of the overlay target 104 (e.g., a boundary associated with outermost features of the overlay target 104) is further used to generate a coarse overlay measurement.

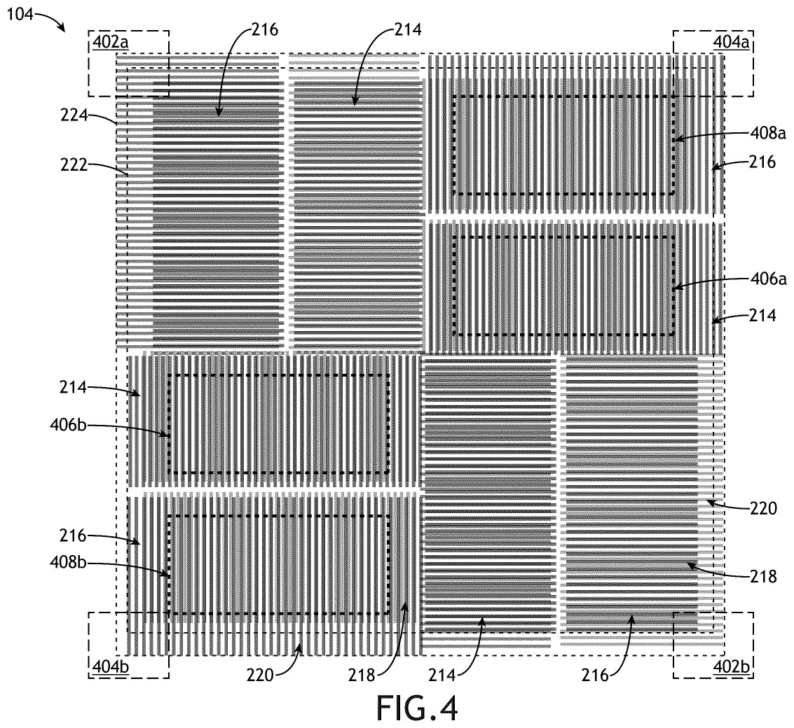

As an illustration, FIG. 4 is a top view of the overlay target 104 in FIG. 2C shown with a physical overlay error, in accordance with one or more embodiments of the present disclosure.

FIG. 4 also depicts ROIs 402a,b including portions of non-overlap regions 220 formed from second-layer features 208 with pitch P located in opposing corners of the overlay target 104, along with ROIs 404a,b including portions of non-overlap regions 220 formed from second-layer features 208 with pitch Q located in different opposing corners of the overlay target 104. The ROIs 402a,b and 404a,b shown in FIG. 4 further include portions of neighboring overlap regions 218, but this is not a requirement.

In this configuration, a coarse overlay measurement may be generated based on a difference between a center of symmetry of the ROIs 402a,b and a center of symmetry of the ROIs 404a,b. These centers of symmetry may be determined using any suitable technique. For example, the center of symmetry of the ROIs 402a,b may be determined by identifying a position at which rotating an image of the ROI 402b provides a peak correlation with an image of the ROI 402a. Similarly, the center of symmetry of the ROIs 404a,b may be determined by identifying a position at which rotating an image of the ROI 404b provides a peak correlation with an image of the ROI 404a.

A fine overlay measurement may then be generated based on portions of overlap regions 218. For example, a fine overlay measurement along the horizontal direction in FIG. 4 may be determined based on a difference between a center of ROIs 230a,b and a center of symmetry of ROIs 232a,b. As above, these centers of symmetry may be determined using any suitable technique. For example, the center of symmetry of the ROIs 230a,b may be determined by identifying a position at which rotating an image of the ROI 406b provides a peak correlation with an image of the ROI 406a. Similarly, the center of symmetry of the regions of interest 232a,b may be determined by identifying a position at which rotating an image of the ROI 408b provides a peak correlation with an image of the ROI 408a.

Notably, the physical overlay error may induce a shift of the Moiré fringes with Moiré pitch pₘ in the ROIs 230a,b (and thus a shift in the center of symmetry of the ROIs 230a,b) along one direction, as well as a shift of the Moiré fringes with Moiré pitch pₘ in the ROIs 232a,b (and thus a shift in the center of symmetry of the ROIs 232a,b) along an opposite direction. Further, the magnitude of these Moiré fringe shifts may be amplified by a Moiré gain factor associated with differences between the pitches of the first-layer features 204 and the second-layer features 208 (e.g., a difference between pitch P and pitch Q). As a result, the fine overlay measurement may be more accurate than the coarse overlay measurement, but may suffer from ambiguity due to the periodic nature of the Moiré fringes as described throughout the present disclosure. However, the coarse overlay technique may not suffer from such an ambiguity since it may not rely solely on periodic signals. For example, the ROIs 226a,b (and ROIs 228a,b) may include non-periodic features such as but not limited to, the overlap boundary 222 or the non-overlap boundary 224.

As a result, the ambiguity in the fine overlay measurement may be resolved using any suitable technique such as, but not limited to, adjusting the fine overlay measurement by one or more integer multiples to a value closest to the coarse overlay measurement. Such a technique may be characterized as unwrapping the fine overlay measurement using the coarse overlay measurement in a manner analogous to phase unwrapping techniques known in the art. For instance, the fine overlay measurement may be adjusted by integer multiples of a measurement range that is equivalent to a shift of the Moiré fringes by a full period (e.g., pₘ).

For example, the coarse overlay measurement may be used to provide a direction of a physical overlay error and thus resolve a directional ambiguity when determining a fine overlay measurement. As another example, the coarse overlay measurement may be used to determine when a physical overlay error exceeds a maximum measurement range associated with an unambiguous fine overlay measurement and further used to adjust the fine overlay measurement accordingly. For instance, the maximum measurement range of the fine overlay measurement may be associated with a period of Moiré fringes. In this way, the fine overlay measurement may be adjusted accordingly to resolve an ambiguity associated with the magnitude of a physical overlay error. In another instance, the coarse overlay measurement may be used to determine whether a physical overlay error induces a Moiré fringe shift greater than the Moiré pitch. In this configuration, the coarse overlay measurement may be used to adjust the fine overlay measurement by a value associated with an integer number of a measurement range provided by the fine overlay measurement (e.g., a measurement range limited to ambiguities associated with the periodic Moiré fringes).

It is to be understood, however, that FIG. 4 and the associated description is provided solely for illustrative purposes and should not be interpreted as limiting the scope of the present disclosure. For example, the coarse overlay measurement and the fine overlay measurement may be determined using any suitable technique based on any suitable ROIs.

Referring now to 1B, additional aspects of the overlay metrology system 100 are described in greater detail, in accordance with one or more embodiments of the present disclosure.

In embodiments, the illumination sub-system 102 includes an illumination source 120 configured to generate illumination 108 to be directed to the sample 106. The illumination 108 may include one or more selected wavelengths of light including, but not limited to, vacuum ultraviolet radiation (VUV), deep ultraviolet radiation (DUV), ultraviolet (UV) radiation, visible radiation, or infrared (IR) radiation. The illumination 108 may further include any range of selected wavelengths. In another embodiment, the illumination source 120 may include a spectrally-tunable illumination source to generate illumination 108 having a tunable spectrum.

The illumination source 120 may further produce illumination 108 having any temporal profile. For example, the illumination source 120 may produce continuous-wave (CW) illumination 108, pulsed illumination 108, or modulated illumination 108. Additionally, the illumination 108 may be delivered via free-space propagation or guided light (e.g. an optical fiber, a light pipe, or the like).

The illumination source 120 may include any type of illumination source suitable for providing illumination 108 in the form of at least one illumination beam. In some embodiments, the illumination source 120 is a laser source. For example, the illumination source 120 may include, but is not limited to, one or more narrowband laser sources, a broadband laser source, a supercontinuum laser source, a white light laser source, or the like. In this regard, the illumination source 120 may provide illumination 108 having high coherence (e.g., high spatial coherence and/or temporal coherence). In some embodiments, the illumination source 120 includes a laser-sustained plasma (LSP) source. For example, the illumination source 120 may include, but is not limited to, a LSP lamp, a LSP bulb, or a LSP chamber suitable for containing one or more elements that, when excited by a laser source into a plasma state, may emit broadband illumination. In some embodiments, the illumination source 120 includes a lamp source. For example, the illumination source 120 may include, but is not limited to, an arc lamp, a discharge lamp, an electrode-less lamp, or the like. In this regard, the illumination source 120 may provide illumination 108 having low coherence (e.g., low spatial coherence and/or temporal coherence).

In embodiments, the illumination sub-system 102 includes one or more illumination sub-system lenses 122 (e.g., to collimate the illumination 108, to relay pupil and/or field planes, or the like). In some embodiments, the illumination sub-system 102 includes one or more illumination sub-system optics 124 to shape or otherwise control the illumination 108. For example, the illumination sub-system optics 124 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the imaging sub-system 110 includes various optical elements to collect the sample signal 112 and image the sample 106 (e.g., image one or more overlay targets 104 on the sample 106) onto on one or more detectors 126. The imaging sub-system 110 may further include one or more optical elements suitable for modifying and/or conditioning the sample signal 112 from the sample 106. In some embodiments, the imaging sub-system 110 includes one or more collection sub-system lenses 128 (e.g., to collimate the sample signal 112, to relay pupil and/or field planes, or the like), which may include, but is not required to include, the objective lens 132. In some embodiments, the imaging sub-system 110 includes one or more collection sub-system optics 130 to shape or otherwise control the sample signal 112. For example, the collection sub-system optics 130 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The illumination sub-system 102 and the imaging sub-system 110 may be arranged in any configuration suitable for illuminating the sample 106 (e.g., illuminating one or more overlay targets 104 on the sample 106) and imaging the sample 106 (e.g., imaging one or more overlay targets 104 on the sample 106) based on at least a portion of collected sample signal 112. For example, as depicted in FIG. 1B, the overlay metrology system 100 may include an objective lens 132 and a beamsplitter 134 to both direct illumination 108 to the sample 106 and collect sample signal 112 from the sample 106 for imaging. As another example, the illumination sub-system 102 and the imaging sub-system 110 include separate optical elements for directing illumination 108 to the sample 106 and collecting sample signal 112 from the sample 106 for imaging. Such optical elements may include objective lenses or any other suitable optical elements.

The overlay metrology system 100 may further include various components to position the sample 106 during imaging. For example, the overlay metrology system 100 may include one or more translation stages 136 to position the sample 106 with respect to the illumination 108, which may be secured by a chuck (not shown). A translation stage 136 may include any type of actuator known in the art and may provide motion along any direction or combination of directions. For instance, the overlay metrology system 100 may include any combination of linear, angular, or tip/tilt translation stages 136. As another example, the overlay metrology system 100 may include beam-scanning optics to position the illumination 108 with respect to the sample 106. Any suitable beam-scanning optics may be utilized including, but not limited to, translatable mirrors, an f-theta lens, or the like.

The imaging sub-system 110 may operate in a static measurement mode and/or a scanning measurement mode. In a static measurement mode, the sample 106 may be stationary relative to the illumination 108 during imaging. In a scanning measurement mode, the sample 106 may be in motion relative to the illumination 108 during imaging (e.g., via any combination of translation stages 136 or beam-scanning optics).

The imaging sub-system 110 may generally include any number or type of detectors 126 suitable for generating one or more images of a sample 106. For example, a detector 126 may include a two-dimensional pixel array (e.g., a focal plane array) such as, but not limited to, a charge-coupled device (CCD) or a complementary metal-oxide semiconductor (CMOS) device. As another example, a detector 126 may include an array of single-pixel sensors such as, but not limited to, photodiodes. As another example, a detector 126 may include a time-delay integration (TDI) sensor.

Referring now to FIG. 1C, additional aspects of the overlay metrology system 100 are described in greater detail, in accordance with one or more embodiments of the present disclosure.

The overlay metrology system 100 may include, but is not limited to, an electron beam illumination source 120 to generate illumination 108 in the form of an electron beam, one or more electron-optical elements 140, one or more electron-optical elements 142, and detector 126 including one or more electron sensors 138.

In embodiments, the electron beam source 120 is configured to direct one or more electron beams of illumination 108 to the sample 106. The electron beam illumination source 120 may form an electron-optical column. In embodiments, the electron beam illumination source 120 includes one or more electron-optical elements 140 configured to focus and/or direct the one or more electron beams of illumination 108 to the surface of the sample 106. In embodiments, the overlay metrology system 100 includes one or more electron-optical elements 142 configured to collect secondary and/or backscattered electrons (e.g., sample signal 112) emanating from the surface of the sample 106 in response to the one or more electron beams of illumination 108. It is noted herein that the one or more electron-optical elements 140 and the one or more electron-optical elements 142 may include any electron-optical elements configured to direct, focus, and/or collect electrons including, but not limited to, one or more deflectors, one or more electron-optical lenses, one or more condenser lenses (e.g., magnetic condenser lenses), one or more objective lenses (e.g., magnetic condenser lenses), or the like.

It is further noted that the overlay metrology system 100 may include any number and type of electron-optical elements necessary to direct/focus the one or more electron beams of illumination 108 onto the sample 106 and, in response, collect and image the sample 106 based on any type of sample signal 112.

For example, the overlay metrology system 100 may include one or more electron beam scanning elements (not shown), which may include, but are not limited to, one or more electromagnetic scanning coils or electrostatic deflectors suitable for controlling a position of the one or more electron beams of illumination 108 relative to the surface of the sample 106. Further, the one or more scanning elements may be utilized to scan the one or more electron beams of illumination 108 across the sample 106 in a selected pattern.

In embodiments, secondary and/or backscattered electrons (e.g., sample signal 112) are directed to one or more sensors 138 of the electron detector 126. The electron detector 126 may include any components or combination of components suitable for detecting backscattered and/or secondary electrons (e.g., sample signal 112) emanating from the surface of the sample 106. In one embodiment, the electron detector 126 includes an electron detector array. In this regard, the electron detector 126 may include an array of electron-detecting portions. Further, each electron-detecting portion of the detector array of the electron detector 126 may be positioned to detect an electron signal from sample 106 associated with one of the incident electron beams of illumination 108. The electron detector 126 may include any type of electron detector known in the art. For example, the electron detector 126 may include a micro-channel plate (MCP), a PIN or p-n junction detector array, such as, but not limited to, a diode array or avalanche photo diodes (APDs). By way of another example, the electron detector 126 may include a high-speed scintillator or a photomultiplier tube (PMT) detector.

While FIG. 1C illustrates the overlay metrology system 100 as including an electron detector 126 comprising only a secondary electron detector assembly, this is not to be regarded as a limitation of the present disclosure. In this regard, it is noted that the electron detector 126 may include, but is not limited to, a secondary electron detector, a backscattered electron detector, and/or a primary electron detector (e.g., an in-column electron detector). In another embodiment, the overlay metrology system 100 may include multiple electron detectors 126. For example, overlay metrology system 100 may include a secondary electron detector assembly, a backscattered electron detector assembly, and an in-column electron detector assembly.

Referring again to FIG. 1A, the one or more processors 116 of a controller 114 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 116 may include any device configured to execute algorithms and/or instructions (e.g., program instructions stored in memory). In some embodiments, the one or more processors 116 may be embodied as a desktop computer, mainframe computer system, workstation, image computer, parallel processor, networked computer, or any other computer system configured to execute a program configured to operate or operate in conjunction with the overlay metrology system 100, as described throughout the present disclosure. Moreover, different subsystems of the overlay metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 114 may include one or more controllers housed in a common housing or within multiple housings. In this way, any controller or combination of controllers may be separately packaged as a module suitable for integration into overlay metrology system 100.

The memory 118 may include any storage medium known in the art suitable for storing program instructions executable by the associated one or more processors 116. For example, the memory 118 may include a non-transitory memory medium. By way of another example, the memory 118 may include, but is not limited to, a read-only memory (ROM), a random-access memory (RAM), a magnetic or optical memory device (e.g., disk), a magnetic tape, a solid-state drive and the like. It is further noted that the memory 118 may be housed in a common controller housing with the one or more processors 116. In some embodiments, the memory 118 may be located remotely with respect to the physical location of the one or more processors 116 and the controller 114. For instance, the one or more processors 116 of the controller 114 may access a remote memory (e.g., server), accessible through a network (e.g., internet, intranet and the like).

The controller 114 may direct (e.g., through control signals) or receive data from any components of the overlay metrology system 100. In this way, the controller 114 may execute or control the execution of any process steps disclosed herein. For example, the processors 116 of the controller 114 may be configured to execute program instructions stored on the memory 118, where the program instructions are configured to cause the processors 116 to execute or control the execution of any process steps disclosed herein.

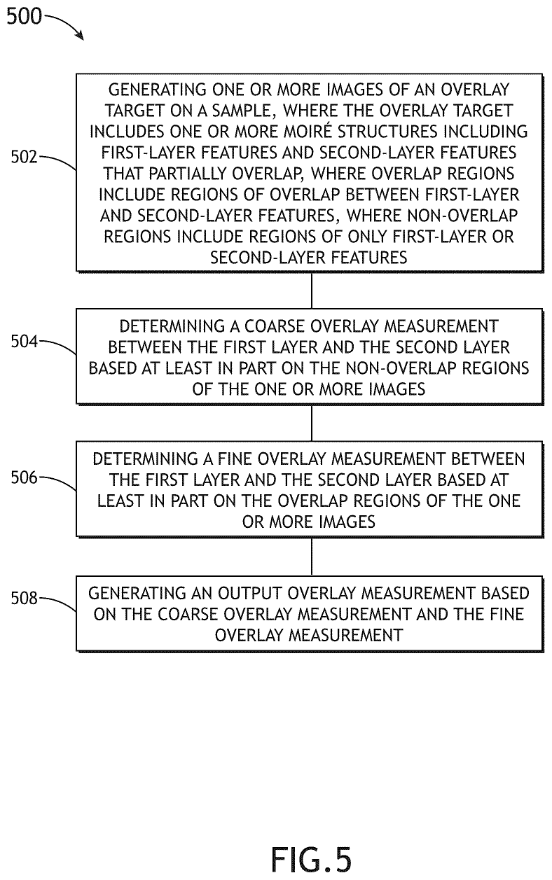

Referring now to FIG. 5, FIG. 5 is a flow diagram illustrating steps performed in a method 500 for overlay metrology, in accordance with one or more embodiments of the present disclosure. Applicant notes that the embodiments and enabling technologies described previously herein in the context of the overlay metrology system 100 should be interpreted to extend to the method 500. It is further noted, however, that the method 500 is not limited to the architecture of the overlay metrology system 100.

In embodiments, the method 500 includes a step 502 of generating one or more images of an overlay target 104 on a sample 106, where the overlay target 104 includes one or more Moiré structures 202 as described herein. For example, a Moiré structure 202 may be formed from first-layer features 204 on a first layer 206 of the sample 106 and second-layer features 208 on a second layer 210 of the sample 106, where the first-layer features 204 and the second-layer features 208 have different pitches and partially overlap. Further, one or more overlap regions 218 of the overlay target 104 may include regions of overlap between the first-layer features 204 and the second layer features 208. One or more non-overlap regions of the overlay target 104 may include regions of non-overlap with one of the first-layer features 204 or the second-layer features 208. The one or more non-overlap regions may further include one or more non-overlapping features such as, but not limited to, an overlap boundary 222 between an overlap region 218 and a non-overlap region 220, an outer boundary of the overlay target 104, or a non-overlap boundary 224 bounding a non-overlap region 220. In this way, a coarse overlay measurement based on the one or more non-overlap regions 220 may not suffer from ambiguity associated with a periodic signal.

Further, the images generated in step 502 may be generated using any technique known in the art. For example, the images generated in step 502 may be generated using light and/or particle beams as illumination 108.

In embodiments, the method 500 includes a step 504 of determining a coarse overlay measurement between the first layer 206 and the second layer 210 based at least in part on the one or more non-overlap regions of the one or more images. The step 504 of determining a coarse overlay may be implemented using any suitable technique based on any signals within the one or more images. For example, the coarse overlay measurement may be based on a difference between centers of symmetry between ROIs that include at least a portion of one or more non-overlap regions 220 (e.g., ROIs including corner regions of the overlay target 104).

In embodiments, the method 500 includes a step 506 of determining a fine overlay measurement between the first layer 206 and the second layer 210 based at least in part on the one or more overlap regions of the one or more images. The step 506 of determining a fine overlay measurement may be implemented using any suitable technique based on any signals within the one or more images. For example, the fine overlay measurement may be based on a difference between centers of symmetry between ROIs of Moiré structures 202 within one or more overlap regions 218.

In embodiments, the method 500 includes a step 508 of generating an output overlay measurement based on the coarse overlay measurement and the fine overlay measurement. For example, the coarse overlay measurement may be used to resolve ambiguities in the fine overlay measurement such as, but not limited to, a direction or magnitude of a physical overlay error. As an illustration, ambiguities may arise when measuring relatively large physical overlay errors based on periodic signals (e.g., Moiré fringes), which may be resolved using a coarse overlay measurement generated in step 504. As a result, the method 500 may enable highly accurate measurements with the benefits of the fine overlay measurement technique for potentially large physical overlay errors. In a general sense, the method 500 may enable measurements with the accuracy and sensitivity of the technique used to generate the fine overlay measurements (e.g., in step 506) for any potentially large physical overlay error, where the maximum measurable overlay error may be limited only by the size of the Moiré region 218 and the ability to generate a coarse overlay measurement therefrom.

Additionally, though not shown in FIG. 5, the method 500 may include a step of controlling one or more process tools via one or more control signals based on the output overlay measurement. Any type of process tool is within the spirit and scope of the present disclosure and may include, but is not limited to, a lithography tool (e.g., a scanner, a stepper, or the like), an etching tool, or a polishing tool. The control signals may further provide any combination of feedback and/or feed-forward control. For example, feedback control may be used to compensate for process deviations for samples within a lot. As another example, feed-forward control may be used to adjust future steps performed on a given sample in response to a measured overlay error.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
a controller including one or more processors configured to execute program instructions stored in a memory device, wherein the program instructions are configured to cause the one or more processors to implement a metrology recipe by:
receiving one or more images of an overlay target on a sample, wherein the overlay target comprises:
one or more Moiré structures, wherein a respective one of the one or more Moiré structures is formed from first-layer features with a first pitch on a first layer of the sample and further with second-layer features with a second pitch on a second layer of the sample, wherein the first-layer features and the second-layer features in the respective one of the one or more Moiré structures partially overlap, wherein one or more overlap regions include regions of overlap between the first-layer features and the second-layer features, wherein one or more non-overlap regions include regions of non-overlap with one of the first-layer features or the second-layer features and further include one or more non-overlapping features;
determining a coarse overlay measurement between the first layer and the second layer based at least in part on the one or more non-overlap regions of the one or more images;
determining a fine overlay measurement between the first layer and the second layer based at least in part on the one or more overlap regions of the one or more images; and
generating an output overlay measurement based on the coarse overlay measurement and the fine overlay measurement.

2. The overlay metrology system of claim 1, wherein the program instructions are further configured to cause the one or more processors to implement the metrology recipe by controlling one or more process tools via one or more control signals based on the output overlay measurement.

3. The overlay metrology system of claim 1, wherein the one or more non-overlapping features comprise:
an overlap boundary between one of the one or more overlap regions and one of the one or more non-overlap regions.

4. The overlay metrology system of claim 1, wherein the one or more non-overlapping features comprise:
a non-overlap boundary between one of the one or more non-overlap regions and an outer boundary of the overlay target.

5. The overlay metrology system of claim 1, wherein the one or more non-overlapping features comprise:
an outer boundary of the overlay target.

6. The overlay metrology system of claim 1, wherein generating the output overlay measurement based on the coarse overlay measurement and the fine overlay measurement comprises:
unwrapping the fine overlay measurement using the coarse overlay measurement.

7. The overlay metrology system of claim 1, wherein the fine overlay measurement has a measurement range, wherein generating the output overlay measurement based on the coarse overlay measurement and the fine overlay measurement comprises:
adjusting the fine overlay measurement by an integer number of the measurement range based on the coarse overlay measurement.

8. The overlay metrology system of claim 1, wherein the overlay target provides the output overlay measurement along one or more measurement directions, wherein the overlay target includes:
a first set of Moiré structures, wherein the first-layer features in the first set of Moiré structures have a pitch P and the second-layer features in the first set of Moiré structures have a pitch Q; and
a second set of Moiré structures, wherein the first-layer features in the second set of Moiré structures have the pitch Q and the second-layer features in the second set of Moiré structures have the pitch P.

9. The overlay metrology system of claim 1, wherein the one or more Moiré structures includes two or more Moiré structures, wherein at least one of the two or more Moiré structures has periodicity along a first measurement direction, wherein at least one of the two or more Moiré structures has periodicity along a second measurement direction different than the first measurement direction, wherein the output overlay measurement includes a first output overlay measurement associated with the first measurement direction and a second output overlay measurement associated with the second measurement direction.

10. An overlay metrology system comprising:
an imaging sub-system including one or more detectors to image a sample in response to illumination from an illumination source; and
a controller communicatively coupled to the imaging sub-system, the controller including one or more processors configured to execute program instructions stored in a memory device, wherein the program instructions are configured to cause the one or more processors to implement a metrology recipe by:
receiving one or more images of an overlay target on the sample from the imaging sub-system, wherein the overlay target comprises:
one or more Moiré structures, wherein a respective one of the one or more Moiré structures is formed from first-layer features with a first pitch on a first layer of the sample and further from second-layer features with a second pitch on a second layer of the sample, wherein the first-layer features and the second-layer features in the respective one of the one or more Moiré structures partially overlap, wherein one or more overlap regions include regions of overlap between the first-layer features and the second-layer features, wherein one or more non-overlap regions include regions of non-overlap with one of the first-layer features or the second-layer features and further include one or more non-overlapping features;
determining a coarse overlay measurement between the first layer and the second layer based at least in part on the one or more non-overlap regions of the one or more images;
determining a fine overlay measurement between the first layer and the second layer based at least in part on the one or more overlap regions of the one or more images; and
generating an output overlay measurement based on the coarse overlay measurement and the fine overlay measurement.

11. The overlay metrology system of claim 10, wherein the imaging sub-system is an optical imaging sub-system, wherein the illumination comprises light.

12. The overlay metrology system of claim 10, wherein the imaging sub-system is a particle-beam imaging sub-system, wherein the illumination comprises at least one of an electron beam, an ion beam, or a neutral-particle beam.

13. The overlay metrology system of claim 10, wherein the program instructions are further configured to cause the one or more processors to implement the metrology recipe by controlling one or more process tools via one or more control signals based on the output overlay measurement.

14. The overlay metrology system of claim 10, wherein the one or more non-overlapping features comprise:
an overlap boundary between one of the one or more overlap regions and one of the one or more non-overlap regions.

15. The overlay metrology system of claim 10, wherein the one or more non-overlapping features comprise:
a non-overlap boundary between one of the one or more non-overlap regions and an outer boundary of the overlay target.

16. The overlay metrology system of claim 10, wherein the one or more non-overlapping features comprise:
an outer boundary of the overlay target.

17. The overlay metrology system of claim 10, wherein generating the output overlay measurement based on the coarse overlay measurement and the fine overlay measurement comprises:
unwrapping the fine overlay measurement using the coarse overlay measurement.

18. The overlay metrology system of claim 10, wherein the fine overlay measurement has a measurement range, wherein generating the output overlay measurement based on the coarse overlay measurement and the fine overlay measurement comprises:
adjusting the fine overlay measurement by an integer number of the measurement range based on the coarse overlay measurement.

19. The overlay metrology system of claim 10, wherein the overlay target provides the output overlay measurement along one or more measurement directions, wherein the overlay target includes:
a first set of Moiré structures, wherein the first-layer features in the first set of Moiré structures have a pitch P and the second-layer features in the first set of Moiré structures have a pitch Q; and
a second set of Moiré structures, wherein the first-layer features in the second set of Moiré structures have the pitch Q and the second-layer features in the second set of Moiré structures have the pitch P.

20. The overlay metrology system of claim 10, wherein the one or more Moiré structures includes two or more Moiré structures, wherein at least one of the two or more Moiré structures has periodicity along a first measurement direction, wherein at least one of the two or more Moiré structures has periodicity along a second measurement direction different than the first measurement direction, wherein the output overlay measurement includes a first output overlay measurement associated with the first measurement direction and a second output overlay measurement associated with the second measurement direction.

21. An overlay method comprising:
generating one or more images of an overlay target on a sample, wherein the overlay target comprises:
one or more Moiré structures, wherein a respective one of the one or more Moiré structures is formed from first-layer features with a first pitch on a first layer of the sample and further from second-layer features with a second pitch on a second layer of the sample, wherein the first-layer features and the second-layer features in the respective one of the one or more Moiré structures partially overlap, wherein one or more overlap regions include regions of overlap between the first-layer features and the second-layer features, wherein one or more non-overlap regions include regions of non-overlap with one of the first-layer features or the second-layer features and further include one or more non-overlapping features;
determining a coarse overlay measurement between the first layer and the second layer based at least in part on the one or more non-overlap regions of the one or more images;
determining a fine overlay measurement between the first layer and the second layer based at least in part on the one or more overlap regions of the one or more images; and
generating an output overlay measurement based on the coarse overlay measurement and the fine overlay measurement.

22. An overlay target comprising:
one or more Moiré structures, wherein a respective one of the one or more Moiré structures is formed from first-layer features with a first pitch on a first layer of a sample and further from second-layer features with a second pitch on a second layer of the sample, wherein the first-layer features and the second-layer features in the respective one of the one or more Moiré structures partially overlap, wherein one or more overlap regions include regions of overlap between the first-layer features and the second-layer features, wherein one or more non-overlap regions include regions of non-overlap with one of the first-layer features or the second-layer features and further include one or more non-overlapping features, wherein an output overlay measurement between the first layer and the second layer is determinable based on a coarse overlay measurement and a fine overlay measurement, wherein the coarse overlay measurement is based at least in part on the one or more non-overlap regions in one or more images, wherein the fine overlay measurement is based at least in part on the one or more overlap regions of the one or more images.

23. The overlay target of claim 22, wherein the one or more non-overlapping features comprise:
an overlap boundary between one of the one or more overlap regions and one of the one or more non-overlap regions.

24. The overlay target of claim 22, wherein the one or more non-overlapping features comprise:
a non-overlap boundary between one of the one or more non-overlap regions and an outer boundary of the overlay target.

25. The overlay target of claim 22, wherein the one or more non-overlapping features comprise:
an outer boundary of the overlay target.

26. The overlay target of claim 22, wherein the overlay target provides the output overlay measurement along one or more measurement directions, wherein the overlay target includes:
a first set of Moiré structures, wherein the first-layer features in the first set of Moiré structures have a pitch P and the second-layer features in the first set of Moiré structures have a pitch Q; and
a second set of Moiré structures, wherein the first-layer features in the second set of Moiré structures have the pitch Q and the second-layer features in the second set of Moiré structures have the pitch P.
